(19) United States
(12) Patent Application Publication
(10) Pub. No.: US 2023/0307255 A1
(43) Pub. Date: Sep. 28, 2023

(54) SYSTEMS AND METHODS FOR CONTROLLING ACCRETION IN SEMICONDUCTOR PROCESSING SYSTEM EXHAUST ARRANGEMENTS

(71) Applicant: ASM IP Holding, B.V., Almere (NL)

(72) Inventors: Gregory Deye, Phoenix, AZ (US); Caleb Miskin, Mesa, AZ (US); Fan Gao, Chandler, AZ (US); Peipei Gao, Chandler, AZ (US)

(21) Appl. No.: 18/187,468

(22) Filed: Mar. 21, 2023

Related U.S. Application Data
(60) Provisional application No. 63/269,759, filed on Mar. 22, 2022.

(51) Int. Cl. H01L 21/67; C23C 16/44; B08B 9/032

(52) U.S. Cl. CPC H01L 21/67017; B08B 9/0325; B08B 9/0328; C23C 16/4405; C23C 16/4412; B08B 2209/032

(57) ABSTRACT

A semiconductor processing system includes a chamber arrangement, an exhaust arrangement connected to the chamber arrangement, an accretion sensor supported within the exhaust arrangement, and a processor. The processor is disposed in communication with the accretion sensor and is responsive to instructions recorded on a non-transitory machine-readable medium to receive an accretion signal from the accretion sensor, the accretion signal indicative of an accretion amount disposed within the exhaust arrangement, receive a predetermined accretion amount value, and compare the accretion amount to the predetermined accretion amount value. The instructions further cause the processor to execute an accretion countermeasure when the received accretion amount is greater than the predetermined accretion amount value. Methods of controlling accretion within exhaust arrangements for semiconductor processing systems and foreline assemblies for semiconductor processing systems are also described.

### FIELD OF INVENTION

The present disclosure generally relates to fabricating semiconductor devices, and more particularly, to controlling accretion in exhaust arrangements for semiconductor processing systems during the fabrication of semiconductor devices.

### BACKGROUND OF THE DISCLOSURE

Semiconductor devices, such as integrated circuit, power electronic, display, and solar devices, are commonly fabrication by depositing a material layer onto a substrate. Material layer deposition generally includes supporting a substrate in a reaction chamber, conditioning the environment within the rection chamber to those suitable for deposition of a material layer onto the substrate, and providing one or more precursors to the reaction chamber. The reaction chamber flows the one or more precursor across the substrate such that the desired material layer deposits onto the substrate, typically according to the environmental conditions within the reaction chamber during the deposition of the material layer, and residual precursor and/or reaction products thereafter (and/or concurrently) issue from the reaction chamber to an exhaust arrangement.

In some material layer deposition techniques a portion of the residual precursor and/or reactants may accrete within the reaction chamber and/or the exhaust arrangement. Absent countermeasure, such residual precursor and/or reaction product accretions can alter the environmental conditions within the reaction chamber during the material layer deposition process. For example, accretion of residual precursor and/or reaction products on interior surfaces of the reaction chamber can alter thermal within the interior of the reaction chamber, such as by changing the transmissivity (or thermal conductivity) of the walls forming the reaction chamber. Accretion of residual precursor and/or reaction products may alter flow conditions within the interior of the reaction chamber, for example, by reducing flow area within the reaction chamber and/or the exhaust arrangement. And accretions of residual precursor and/or reaction products may alter the operation of various devices within the reaction chamber and/or exhaust arrangement, such as by fouling sensors and/or flow control devices arranged within the reaction chamber and/or exhaust arrangement, for example by reducing travel of valve members in flow control device within the exhaust arrangement employed to convey residual precursor and/or reaction products issued by the reaction chamber to the external environment.

Various countermeasures exist to limit influence that residual precursor and/or reaction products may otherwise have on material layer deposition. For example, etchant may periodically be provided to the reaction chamber and/or exhaust arrangement to remove accretions of residual precursor and/or reaction products. The reaction chamber and/or the exhaust arrangement may periodically be disassembled, and accretions of residual precursor and/or reaction products removed from interior surfaces of the disassembled reaction chamber and/or exhaust arrangement components. While generally satisfactory for its intended purpose, efficacy of etching may be limited in regions that are relatively cool, and downtime attendant with disassembly typically limits the availability (and throughput) of the reaction chamber.

Such systems and methods have generally been satisfactory for their intended purpose. However, there remains a need in the art for improved exhaust arrangements, semiconductor processing systems, and methods of controlling accretion in exhaust arrangements for semiconductor processing systems. The present disclosure provides a solution to this need.

### SUMMARY OF THE DISCLOSURE

A semiconductor processing system includes a chamber arrangement, an exhaust arrangement connected to the chamber arrangement, an accretion sensor supported within the exhaust arrangement, and a processor. The processor is disposed in communication with the accretion sensor and is responsive to instructions recorded on a non-transitory machine-readable medium to receive an accretion signal from the accretion sensor, the accretion signal indicative of an accretion amount disposed within the exhaust arrangement, receive a predetermined accretion amount value, and compare the accretion amount to the predetermined accretion amount value. The instructions further cause the processor to execute an accretion countermeasure when the received accretion amount is greater than the predetermined accretion amount value. In addition to one or more of the features described above, or as an alternative, further examples may include

In addition to one or more of the features described above, or as an alternative, further examples of the semiconductor processing system may include that the accretion sensor includes a quartz crystal microbalance (QCM) structure.

In addition to one or more of the features described above, or as an alternative, further examples of the semiconductor processing system may include that the exhaust arrangement comprises a foreline assembly connected to the chamber arrangement, and that the QCM structure is supported within the foreline assembly.

In addition to one or more of the features described above, or as an alternative, further examples of the semiconductor processing system may include that the accretion amount is disposed on the QCM structure.

In addition to one or more of the features described above, or as an alternative, further examples of the semiconductor processing system may that the exhaust arrangement includes an exhaust conduit connected to the chamber arrangement, wherein the accretion sensor is supported within the exhaust conduit.

In addition to one or more of the features described above, or as an alternative, further examples of the semiconductor processing system may include an isolation valve connecting the exhaust conduit to the chamber arrangement, the isolation valve separating the accretion sensor from the chamber arrangement.

In addition to one or more of the features described above, or as an alternative, further examples of the semiconductor processing system may include a pressure control valve arranged along the exhaust conduit, the pressure control valve between the accretion sensor and the chamber arrangement.

In addition to one or more of the features described above, or as an alternative, further examples of the semiconductor processing system may include that the exhaust conduit has an etchant port. The pressure control valve may be between the accretion sensor and the etchant port.

In addition to one or more of the features described above, or as an alternative, further examples of the semiconductor processing system may include an etchant conduit connected to the etchant port and an etchant source connected to the etchant conduit and bypassing the chamber arrangement, etchant provided to the exhaust conduit bypassing the chamber arrangement.

In addition to one or more of the features described above, or as an alternative, further examples of the semiconductor processing system may include a maintenance valve connected to the exhaust conduit, and that the accretion sensor is supported within the exhaust conduit between the maintenance valve and the chamber arrangement.

In addition to one or more of the features described above, or as an alternative, further examples of the semiconductor processing system may include that the etchant source includes chlorine (Cl₂) gas.

In addition to one or more of the features described above, or as an alternative, further examples of the semiconductor processing system may include an exhaust conduit connected to the chamber arrangement, the accretion sensor supported within the exhaust conduit; an etchant conduit connected to the exhaust conduit; and an etchant source connected to the etchant conduit, the etchant conduit bypassing the chamber arrangement.

In addition to one or more of the features described above, or as an alternative, further examples of the semiconductor processing system may include a reducing agent conduit connected to the etchant conduit, a reducing agent supply valve arranged along the reducing agent conduit, and an etchant supply valve arranged along the etchant conduit. The reducing agent conduit may be connected to the etchant conduit between the etchant supply valve and the exhaust conduit to introduce a reducing agent into an etchant provided by the etchant source within the etchant conduit.

In addition to one or more of the features described above, or as an alternative, further examples of the semiconductor processing system may include that the etchant supply valve and the reducing agent supply valve are operably associated with the processor to heat the exhaust conduit using heat generated by reducing the etchant with the reducing agent within the etchant conduit.

In addition to one or more of the features described above, or as an alternative, further examples of the semiconductor processing system may include that the etchant source includes chlorine (Cl₂) gas and that the reducing agent source includes hydrogen (H₂) gas.

In addition to one or more of the features described above, or as an alternative, further examples of the semiconductor processing system may include a precursor delivery arrangement. The precursor delivery arrangement may include a silicon-containing precursor source connected to the chamber arrangement and therethrough to the exhaust arrangement, an etchant source connected to the exhaust arrangement by an etchant conduit, the etchant conduit bypassing the chamber arrangement such that etchant provided to the exhaust arrangement does not traverse the chamber arrangement, and a reducing agent source connected to the etchant conduit such that reducing agent provided to the exhaust arrangement does not traverse the chamber arrangement.

In addition to one or more of the features described above, or as an alternative, further examples of the semiconductor processing system may include that the countermeasure executed by the processor include fluidly separating the exhaust arrangement from the chamber arrangement, fluidly coupling the exhaust arrangement to an etchant source, fluidly coupling the exhaust arrangement to a reducing agent source, and heating the exhaust arrangement using a reducing agent provided by the reducing agent source and an etchant provided by the etchant source.

In addition to one or more of the features described above, or as an alternative, further examples of the semiconductor processing system may include that the chamber arrangement includes a susceptor supported from rotation within a chamber body, the chamber body configured to flow a material layer precursor across a substrate seated on the susceptor.

An accretion control method is provided. The method includes, at a semiconductor processing system as described above, receiving, at the processor, an accretion signal from the accretion sensor indicative of an accretion amount disposed within the exhaust arrangement; receiving, at the processor, a predetermined accretion amount value; comparing, with the processor, the received accretion amount to the predetermined accretion amount value; and executing, with the processor, an accretion countermeasure when the received accretion amount is greater than the predetermined accretion amount value. The countermeasure includes at least one of (a) providing a user output to a user interface operably associated with the processor, (b) fluidly separating the exhaust arrangement from the chamber arrangement, (c) providing an etchant to the exhaust arrangement, and (d) providing a reducing agent to the exhaust arrangement to heat the exhaust arrangement.

A foreline assembly for a semiconductor processing system is provided. The foreline assembly includes an exhaust conduit, an isolation valve and a maintenance valve arranged along the exhaust conduit configured to fluidly couple the semiconductor processing system to an exhaust pump, and a pressure control valve between the isolation valve and the maintenance valve configured to control pressure within a chamber arrangement of the semiconductor processing system. An accretion sensor is arranged within the exhaust conduit between the pressure control valve and the maintenance valve to provide an accretion signal indicating an amount of accretion within the exhaust conduit, and an etchant port is defined along the exhaust conduit between the isolation valve and the pressure control valve to remove accretion from within the exhaust conduit using an etchant using the accretion signal.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system including an exhaust arrangement with an accretion sensor in accordance with the present disclosure, showing an accretion disposed within the exhaust arrangement;

FIG. 2 is a schematic view of the semiconductor processing system of FIG. 1 according to an example, showing a precursor delivery arrangement connected to the chamber arrangement and a controller disposed in communication with the accretion sensor;

FIG. 3 is a schematic view of the semiconductor processing system of FIG. 1 according to an example, showing a material layer being deposited onto s substrate supported within the chamber arrangement;

FIG. 4 is a schematic view of the semiconductor processing system of FIG. 1 according to an example, showing a pressure control valve and an isolation valve fluidly coupling the accretion sensor to the chamber arrangement;

FIG. 5 is a schematic view of another semiconductor processing system constructed in accordance with the present disclosure, showing an etchant source directly connected to the exhaust arrangement to provide etchant to the exhaust arrangement without flowing the etchant through the chamber arrangement;

FIGS. 6 and 7 are schematic views of the semiconductor processing system of FIG. 5 according to another example of the present disclosure, showing an etchant being provided directly to the exhaust arrangement through the etchant conduit when the accretion sensor indicates that accretion disposed within the exhaust arrangement exceeds a predetermined accretion thickness;

FIG. 8 is a schematic view of a further semiconductor processing system constructed in accordance with the present disclosure, showing an etchant source and a reducing agent source connected directly to an exhaust arrangement by a common etchant conduit;

FIGS. 9-11 are schematic views of the semiconductor processing system of FIG. 8, showing an etchant and a reducing agent being provided to the exhaust arrangement by the etchant conduit when the accretion sensor indicates that accretion disposed within the exhaust arrangement exceeds a predetermined accretion thickness; and

FIG. 12 is process flow diagram of a method of controlling accretion within an exhaust arrangement of a semiconductor processing system, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

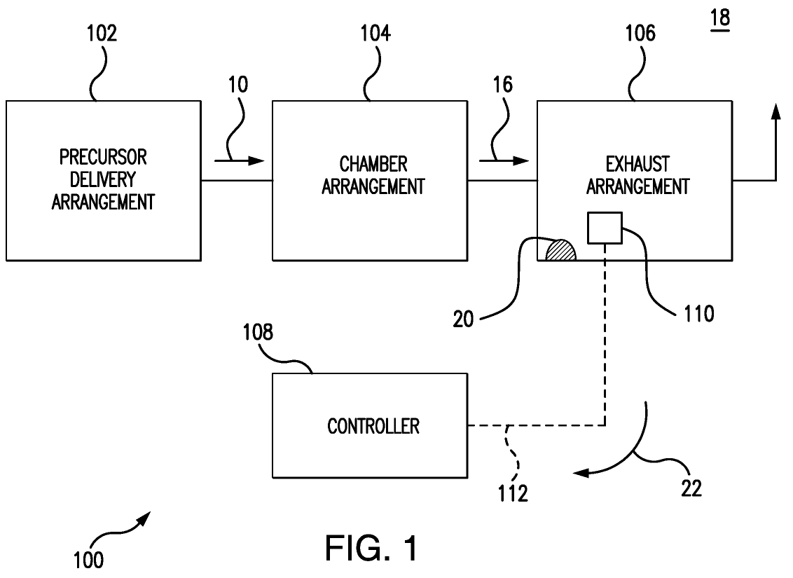

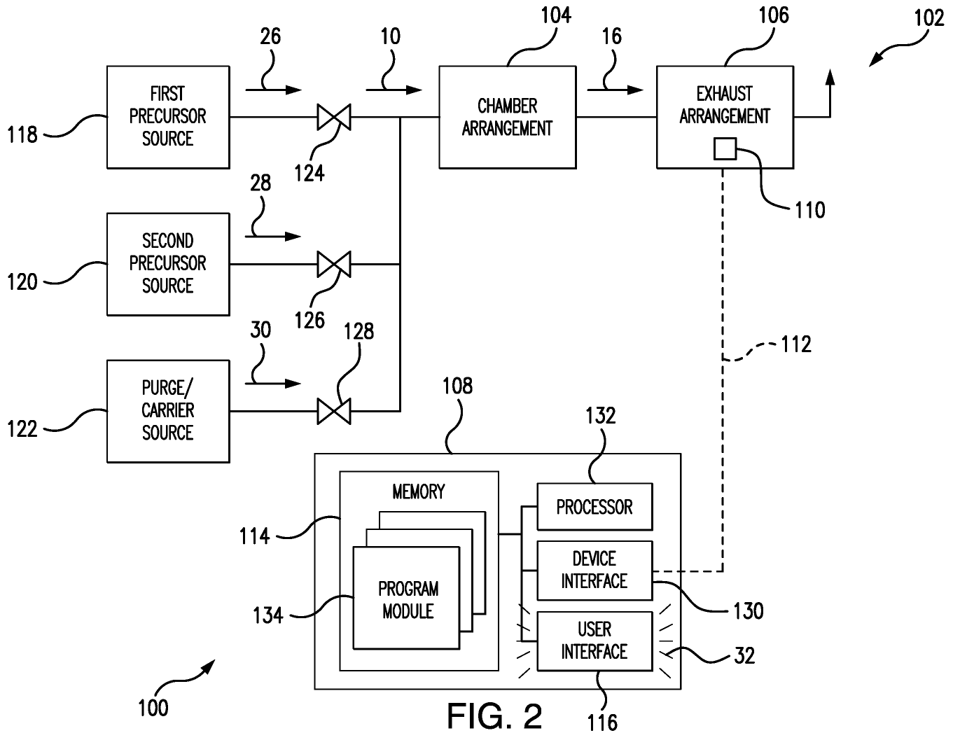

Reference will now be made to the drawings wherein like reference numerals identify similar structural features or aspects of the subject disclosure. For purposes of explanation and illustration, and not limitation, a partial view of an example of semiconductor processing system having an exhaust arrangement with an accretion sensor in accordance with the present disclosure is shown in FIG. 1 and is designated generally by reference character 100. Other examples of semiconductor processing systems and methods of controlling accretion in exhaust arrangements for semiconductor processing systems in accordance with the present disclosure, or aspects thereof, are provided in FIGS. 2-12, as will be described. The systems and methods of the present disclosure may be used for controlling accretion exhaust arrangements for semiconductor processing systems employed for depositing material layers onto substrate, such as epitaxial material layers deposited using chemical vapor deposition (CVD) techniques, although the present disclosure is not limited to any particular deposition technique or semiconductor processing systems employed for material layer deposition in general.

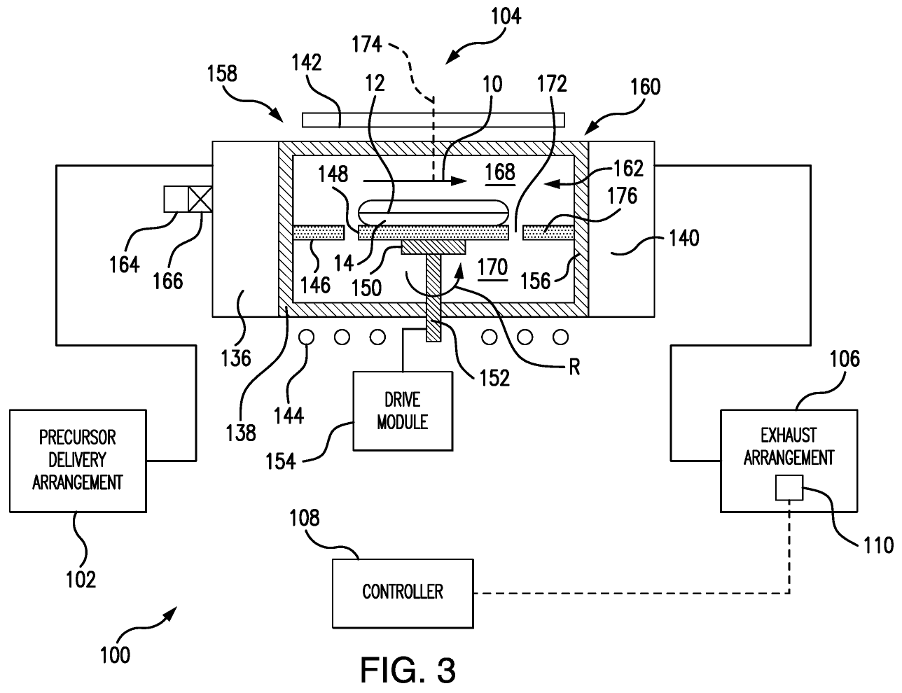

Referring to FIG. 1, the semiconductor processing system 100 is shown. The semiconductor processing system 100 includes a precursor delivery arrangement 102, a chamber arrangement 104, an exhaust arrangement 106, and a controller 108. The precursor delivery arrangement 102 is connected to the chamber arrangement 104 and is configured provide a material layer precursor 10 to the chamber arrangement 104. The chamber arrangement 104 is configured to flow the material layer precursor 10 across a substrate to deposit a material layer onto the substrate, e.g., a material layer 12 (shown in FIG. 3) onto a substrate 14 (shown in FIG. 3) including a semiconductor wafer, and issue residual precursor and/or reaction products 16 to the exhaust arrangement 106. The exhaust arrangement 106 is in turn fluidly coupled to the external environment 18 outside of the semiconductor processing system 100, is fluidly coupled to the chamber arrangement 104, and is configured to communicate the residual precursor and/or reaction products 16 to the external environment 18.

As used herein, the term “substrate” may refer to any underlying material or materials that may be used, or upon which, a device, a circuit, or a film may be formed. The “substrate” may be continuous or non-continuous; rigid or flexible; solid or porous. The substrate may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide by way of non-limiting example. Continuous substrates may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form.

As has been explained, residual precursor and/or reaction products can, in some semiconductor processing systems, from accretions within the exhaust arrangement of the semiconductor processing system, potentially reducing reliability of such semiconductor processing systems and/or influencing quality material layers deposited on substrates using such semiconductor processing systems. For example, residual precursor and/or reaction product accretion within the exhaust arrangement can restrict flow through the exhaust arrangement, influencing the environment within the chamber arrangement and introducing variation into material layers deposited onto substrates in the chamber arrangement. Residual precursor and/or reaction product accretion with the exhaust arrangement can alter operation of flow control devices in the exhaust arrangement, also influencing the environment within the chamber arrangement and introducing variation into material layers deposited onto substrates in the chamber arrangement. To limit (or prevent) the development of residual precursor and/or reaction product accretions, e.g., an accretion 20, within the exhaust arrangement 106, semiconductor processing system 100 includes an accretion sensor 110.

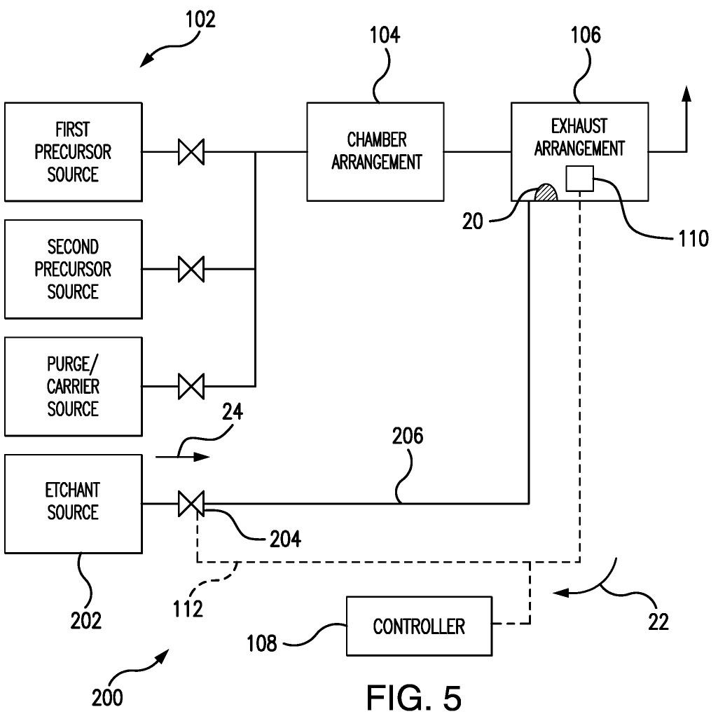

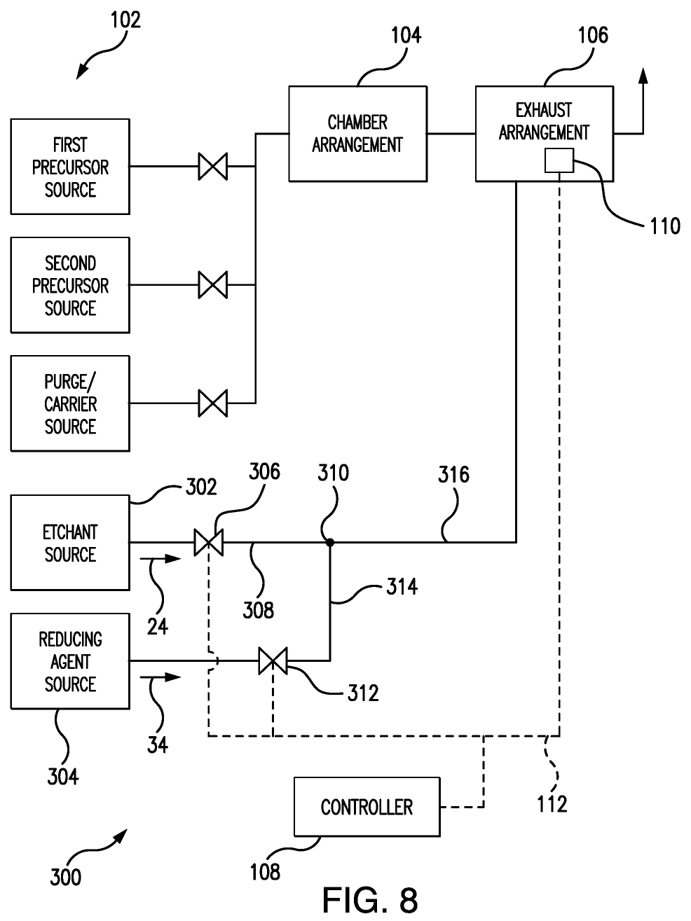

The accretion sensor 110 is supported within the exhaust arrangement 106 and is configured to provide an accretion signal 22 including information indicative an amount of residual precursor and/or reaction products disposed within the exhaust arrangement 106. It is contemplated that the accretion sensor 110 be disposed in communication with the controller 108, e.g., via a wired or wireless link 112, and that accretion sensor 110 provide the accretion signal 22 to the controller 108 via the wired or wireless link 112. The controller 108 is in turn configured to execute one or more countermeasures when the accretion signal indicates that the accretion 20 exceeds a predetermined amount, such as a predetermined thickness. For example, the controller 108 may provide a user output 32 (shown in FIG. 2) to a user interface 116 (shown in FIG. 2) when the accretion signal 22 indicates that the accretion 20 exceeds a predetermined accretion amount value. In certain examples, the controller 108 may cause an etchant, e.g., the etchant 24 (shown in FIG. 5), to be provided to the exhaust arrangement 106 to remove the accretion 20 when the accretion signal 22 indicates that the accretion 20 exceeds the predetermined accretion amount value. In accordance with certain examples, the controller 108 may cause the exhaust arrangement to be heated, by energy related by reduction of the etchant 24 by a reducing agent 34 (shown in FIG. 8), and thereafter removed by a redox product 36 (shown in FIG. 8) when the accretion signal 22 indicates that the accretion 20 exceeds a predetermined accretion amount value. As will be appreciated by those of skill in the art in view of the present disclosure, these countermeasures are illustrative, and that other countermeasures may be undertaken using the accretion signal 22 and remain within the scope of the present disclosure.

With reference to FIG. 2, the precursor delivery arrangement 102 is shown according an example of the present disclosure. As shown in FIG. 2, the precursor delivery arrangement 102 includes a first precursor source 118, a second precursor source 120, and a purge/carrier source 122. The precursor delivery arrangement 102 also includes a first precursor supply valve 124, a second precursor supply valve 126, and a purge/carrier supply valve 128. Although shown with a specific arrangement in FIG. 2, it is to be understood and appreciated that the precursor delivery arrangement 102 may include other elements and/or omit elements shown and remain within the scope of the present disclosure.

The first precursor source 118 includes a silicon-containing precursor 26 and is connected to the first precursor supply valve 124. The first precursor supply valve 124 is in turn connected to the chamber arrangement 104, fluidly couples the first precursor source 118 to the chamber arrangement 104, and is configured to provide a flow of the silicon-containing precursor 26 to the chamber arrangement 104. In certain examples the silicon-containing precursor 26 may include silane (SiH₄). In accordance with certain examples, the silicon-containing precursor 26 may include dichlorosilane (H₂SiCl₂) or trichlorosilane (HCl₃Si). It is also contemplated that, in accordance with certain examples, the first precursor source 118 may be connected to the exhaust arrangement 106 by a vent conduit and a first precursor vent valve, the silicon-containing precursor 26 flowing to the exhaust arrangement 106 and bypassing the chamber arrangement 104 through the first precursor vent valve and the vent conduit.

The second precursor source 120 includes a dopant-containing precursor 28 and is connected to the second precursor supply valve 126. The second precursor supply valve 126 is in turn connected to the chamber arrangement 104, fluidly couples the second precursor source 120 to the chamber arrangement 104, and is configured to provide a flow of the dopant-containing precursor 28 to the chamber arrangement 104. In certain examples the dopant-containing precursor 28 may include germanium, such as germane (GeH₄) by way of non-limiting example. In accordance with certain examples, the dopant-containing precursor 28 may include an n-type dopant or a p-type dopant. Examples of suitable n-type and p-type dopants include those containing arsenic (As), boron (B), and phosphorous (P). It is contemplated that the second precursor source 120 may be connected to the exhaust arrangement 106 by the vent conduit and a second precursor vent valve, the dopant-containing precursor 28 flowing to the exhaust arrangement 106 and bypassing the chamber arrangement 104 through the second precursor vent valve and the vent conduit.

The purge/carrier source 122 includes a purge/carrier gas 30 and is connected to the purge/carrier supply valve 128. The purge/carrier supply valve 128 in turn is connected to the chamber arrangement 104, fluidly couples the purge/carrier supply valve 128 to the chamber arrangement 104, and is configured to provide a flow of the purge/carrier gas 30 to the chamber arrangement 104. In certain examples the purge/carrier gas 30 may include (or consist of or consist essentially of) an inert gas, such as nitrogen (N₂) gas or argon (Ar) gas. In accordance with certain examples, the purge/carrier gas 30 may include hydrogen (H₂) gas. It is contemplated that the purge/carrier source 122 may be connected to the exhaust arrangement 106 by the vent conduit and a purge/carrier vent valve, the purge/carrier gas 30 flowing to the exhaust arrangement 106 and bypassing the chamber arrangement 104 through the purge/carrier vent valve and the vent conduit.

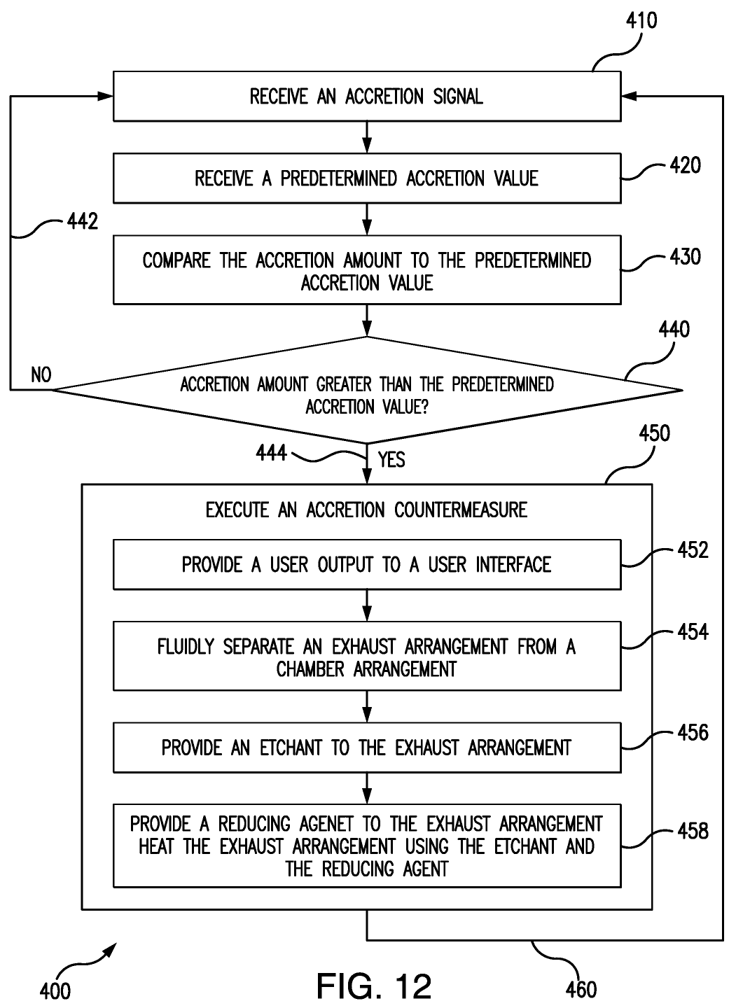

As also shown in FIG. 2, the controller 108 may include the memory 114, the user interface 116, a device interface 130, and a processor 132. The device interface 130 connects the controller 108 to the wired or wireless link 112 and provides communication between the accretion sensor 110 and the processor 132. The processor 132 is in turn operably connected to the user interface 116 and is disposed in communication with the memory 114. The memory 114 includes a non-transitory machine-readable medium having a plurality of program modules 134 recorded thereon that, when read by the processor 132, cause the processor 132 to execute certain operations. Among the operations are operations of an accretion control method 400 (shown in FIG. 12), as will be described. Although a particular architecture of the controller 108 is shown in FIG. 2 and described herein, it is to be understood and appreciated that the controller 108 may have other architectures in examples of the present disclosure, such as distributed computing architectures, and remain within the scope of the present disclosure.

With reference to FIG. 3, the chamber arrangement 104 is shown according to an example. In the illustrated example the chamber arrangement 104 includes an injection flange 136, a chamber body 138, and an exhaust flange 140. The chamber arrangement 104 also includes an upper lamp array 142, a lower lamp array 144, and a divider 146. The chamber arrangement 104 further includes a susceptor 148, a susceptor support 150, a shaft 152, and a drive module 154. Although shown and described herein as single-substrate crossflow chamber arrangement, it is to be understood and appreciated that the chamber arrangement 104 in other examples, such as mini-batch and batch arrangements, and remain within the scope of the present disclosure.

The chamber body 138 is formed from a transmissive material 156, has an injection end 158 and a longitudinally opposite exhaust end 160, and is configured to flow the material layer precursor 10 across the substrate 14 during deposition of the material layer 12 onto the substrate 14. In certain examples the transmissive material 156 may be a ceramic material, such as quartz. In accordance with certain examples, the chamber body 138 may have a plurality of external ribs extending laterally around the chamber body 138 and longitudinally spaced apart from the one another between the injection end 158 and the exhaust end 160 of the chamber body 138. It is also contemplated that the chamber body 138 may be have no external ribs.

The injection flange 136 is connected to the injection end 158 of the chamber body 138, fluidly couples the precursor delivery arrangement 102 to an interior 162 of the chamber body 138, and configured to provide access to the interior 162 of the chamber body 138 for a substrate handling robot 164 through a gate valve 166. The exhaust flange 140 is connected to the exhaust end 160 of the chamber body 138, fluidly couples the interior 162 of the chamber body 138 to the exhaust arrangement 106, and is configured to communicate the residual precursor and/or reaction products 16 issued by the chamber body 104 to the exhaust arrangement 106. In certain examples the exhaust flange 140 may be as shown and described in U.S. Pat. No. 10,612,136 to Sreeram et al., issued on Apr. 7, 2020, the contents of which are incorporated herein by reference in its entirety.

The upper lamp array 142 is supported above the chamber body 138 (relative to gravity), includes a plurality of linear lamps, and is radiantly coupled to the interior 162 of the chamber body 138 by the transmissive material 156 forming an upper wall of the chamber body 138. The lower lamp array 144 is similar to the upper lamp array 142, is additionally supported below the chamber body 138, and is radiantly coupled to the interior 162 of the chamber body 138 by the transmissive material 156 forming a lower wall of the chamber body 138. It is contemplated that the upper lamp array 142 and the lower lamp array 144 be configured to radiantly heat the substrate 14 using electromagnetic radiation emitted by the plurality of linear lamps included in the upper lamp array 142 and the lower lamp array 144, such as electromagnetic radiation in an infrared waveband. In certain examples, the upper lamp array 142 may extend longitudinally between the injection end 158 and the exhaust end 160 of the chamber body 138. In accordance with certain examples, the lower lamp array 144 may extend laterally below the chamber body 138. It is also contemplated that the linear lamps included in the lower lamp array 144 may be angled, e.g., orthogonal, relative the linear lamps included in the upper lamp array 142.

The divider 146 is seated within the interior 162 of the chamber body 138, divides the interior 162 of the chamber body 138 into an upper chamber 168 and a lower chamber 170, and has an aperture 172 extending therethrough. The aperture 172 fluidly couples the upper chamber 168 to the lower chamber 170 of the chamber body 138 and extends about a rotation axis 174. In certain examples, the divider 146 may be formed from an opaque material 176, which is opaque relative electromagnetic radiation emitted by the upper lamp array 142 and the lower lamp array 144. Examples of suitable opaque materials include silicon carbide coated graphite.

The susceptor 148 is arranged within the aperture 172, is supported for rotation about the rotation axis 174, and is fixed in rotation relative to the susceptor support 150. The susceptor support 150 is arranged along the rotation axis 174, couples the susceptor 148 to the shaft 152, and is fixed in rotation relative to the shaft 152. The shaft 152 extends along the rotation axis 174 and through the lower wall of the chamber body 138, and couples the drive module 154 to the susceptor 148. The drive module 154 is operably associated with the shaft 152, and therethrough the susceptor support 150 and the susceptor 148, and is configured to rotate R the susceptor 148 about the rotation axis 174. In certain examples, the susceptor 148 may be formed from the opaque material 176. In accordance with certain examples, either or both the susceptor support 150 and the shaft 152 may be formed from the transmissive material 156 forming the chamber body 138.

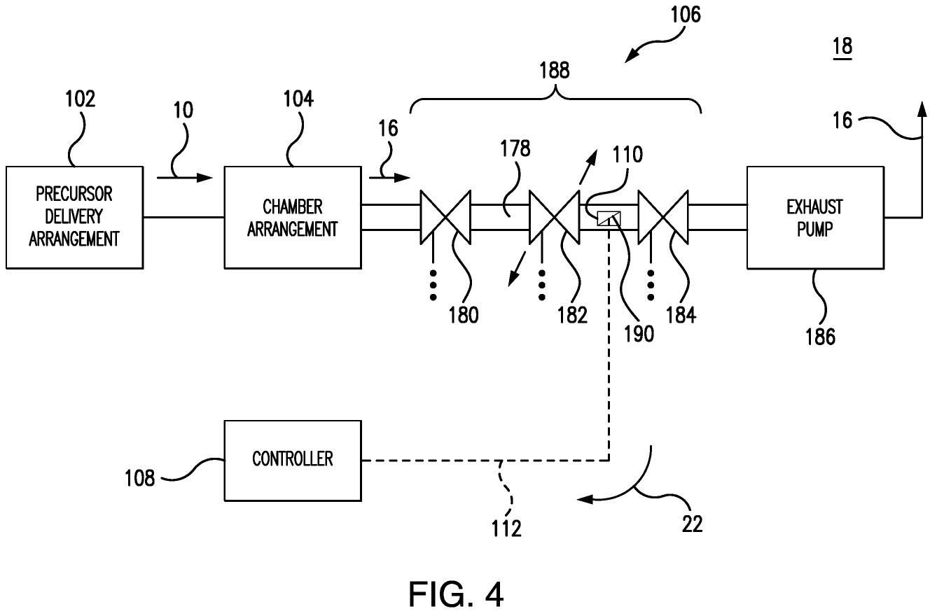

With reference to FIG. 4, the exhaust arrangement 106 is shown according to an example. In the illustrated example the exhaust arrangement 106 includes an exhaust conduit 178, an isolation valve 180, and a pressure control valve 182. The exhaust arrangement 106 also includes a maintenance valve 184, an exhaust pump 186, and the accretion sensor 110. In certain examples the exhaust conduit 178, the pressure control valve 182, and the accretion sensor 110 may be arranged as a foreline assembly 188, which allows for packaging elements of the exhaust arrangement 106 with the chamber arrangement 104 and limits the footprint of the semiconductor processing system 100. Although shown and described as having certain elements, it is to be understood and appreciated that the exhaust arrangement 106 may have a different arrangement in other examples and remain within the scope of the present disclosure.

The exhaust conduit 178 fluidly couples the exhaust pump 186 to the chamber arrangement 104 and is configured to communicate the residual precursor and/or reaction products 16 issued by the chamber body 104 to the exhaust pump 186. The exhaust pump 186 in turn fluidly couples the exhaust conduit 178 to the external environment 18 outside of the semiconductor processing system 100 and is configured to communicate the residual precursor and reaction products 16 issued by the chamber arrangement 104 to the external environment 18. In certain examples, the exhaust pump 186 may include a vacuum pump.

The isolation valve 180 connects the exhaust conduit 178 to the chamber arrangement 104 and is configured to provide selective fluid communication between the exhaust conduit 178 and the chamber arrangement 106. In this respect it is contemplated that the isolation valve 180 have a valve member supported therein with an open position, wherein the isolation valve 180 fluidly couples the exhaust conduit 178 to the chamber arrangement 104, and a closed position, wherein the isolation valve 180 fluidly separates the exhaust conduit 178 from the chamber arrangement 104. In certain examples, the isolation valve 180 may include a manual actuator for manual movement of the valve member within the isolation valve 180 between the open position and the closed position. In accordance with certain examples, the isolation valve 180 may include an electrical actuator, such as a solenoid, for movement of the valve member within the isolation valve 180 between the open position and the closed position. In such examples the isolation valve 180 may be operably associated with the controller 108 for opening and closing of the isolation valve 180. As will also be appreciated by those of skill in the art in view of the present disclosure, closure of the isolation valve 180 facilitates servicing the exhaust conduit 178 and/or the pressure control valve 182.

The maintenance valve 184 connects the exhaust conduit 178 to the exhaust pump 186 and is configured to provide selective fluid communication between the exhaust conduit 178 and the exhaust pump 186. In this respect it is contemplated that the maintenance valve 184 have an open position, wherein the maintenance valve 184 fluidly couples the exhaust conduit 178 to the exhaust pump 186, and a closed position, wherein the maintenance valve 184 separates the exhaust conduit 178 from the exhaust pump 186. In certain examples, the maintenance valve 184 may include a manual actuator for manual movement of a valve member movable within the maintenance valve 184 between the open position and the closed position. In accordance with certain examples, the maintenance valve 184 may include an electrical actuator, such as a solenoid, for movement of the valve member between the open position and the closed position. In such examples the maintenance valve 184 may be operably associated with the controller 108 for opening and closing of the maintenance valve 184. As will also be appreciated by those of skill in the art in view of the present disclosure, closure of the maintenance valve 184 also facilitates servicing of the exhaust conduit 178 and/or the pressure control valve 182.

The pressure control valve 182 is arranged along the exhaust conduit 178 between the isolation valve 180 and the maintenance valve 184, is fluidly downstream of the isolation valve 180 relative to the general direction of flow between the chamber arrangement 104 and the exhaust pump 186, and is configured to control pressure within the chamber arrangement 104. In certain examples, the pressure control valve 182 may include a throttling member supported therein for adjusting effective flow area between the chamber arrangement 104 and the exhaust pump 186. In accordance with certain examples, the pressure control valve 182 may include an electrical actuator, such as solenoid or a servo actuator, and may be operably associated with the controller 108. Pressure control within the chamber arrangement 104 may be accomplished, for example, via cooperation of a throttling member position schedule maintained in memory and pressure measurements acquired from within the chamber arrangement 104. As will appreciated by those of skill in the art in view of the present disclosure, other modes of pressure control valve operation are possible and remain within the scope of the present disclosure.

The accretion sensor 110 is supported within the exhaust arrangement 106 to provide the accretion signal 22 to the controller 108. More specifically, the accretion sensor 110 is supported within the exhaust conduit 178 between the isolation valve 180 and the maintenance valve 184 to provide the accretion signal 22 to the controller 108. Specifically, the accretion sensor 110 is supported within the exhaust conduit 178 between the pressure control valve 182 and the maintenance valve 184 to provide the accretion signal 22 to the controller 108. It is contemplated that the accretion signal 22 include information indicative of an amount of accretion disposed within the exhaust arrangement 106. In certain examples, the accretion signal 22 may be indicative of an amount accretion disposed directly on the accretion sensor 110. In accordance with certain examples, the accretion signal 22 may be indicative of an amount of accretion disposed at another location within the exhaust arrangement 106, for example, within the pressure control valve 182. This may be accomplished, for example, by applying a voltage offset to an output of the accretion sensor 110 corresponding to temperature or flow differential between the position of accretion sensor 110 and the pressure control valve 182.

In certain examples, the accretion sensor 110 may include a quartz crystal microbalance (QCM) structure 190. The QCM structure 190 may supported within the exhaust conduit 178, such as on interior surface or centrally positioned within the flow area of the exhaust conduit 178 on a bracket member such that the QCM structure 190 is exposed to same exhaust gas flow conditions that other structures within the exhaust conduit 178 experience. It is also contemplated that the QCM structure 190 may be in communication with the exhaust conduit 178 through a port and/or a tap member, facilitating service of the QCM structure 190. Advantageously, employment of the QCM structure 190 provides the ability to detect the accumulation of relatively small amounts of accretion at the location of the QCM structure 190 and/or directly, at least in part, on the QCM structure 190 itself. The ability to detect relatively small amounts of accretion in turns allows the accretion sensor 110 to be positioned at locations where accretion accumulation is relatively slow, e.g., within a cul-de-sac conduit (or tap) connected to the exhaust conduit 178 at a port or union, and the detected accumulation correlated to accumulation at locations within the exhaust arrangement 106 subject to more rapid accumulation of accretion. As will be appreciated by those of skill in the art in view of the present disclosure, this can prolong the expected service life of the accretion sensor 110. Examples of suitable QCM structures include 750-7000-GXX Sensors, available from INFICON GmbH of Bad Ragaz, Switzerland.

With reference to FIG. 5, a semiconductor processing system 200 is shown. The semiconductor processing system 200 is similar to the semiconductor processing system 100 (shown in FIG. 1) and additionally includes an etchant source 202, an etchant supply valve 204, and an etchant supply conduit 206. The etchant source 202 include an etchant 24, is connected to the etchant supply valve 204, and is configured to provide a flow of the etchant 24 to the exhaust arrangement 106. In certain examples, the etchant 24 may include a halide, such as chlorine. In accordance with certain examples, the etchant 24 may include (e.g., consist of or consist essentially of) chlorine (Cl2) gas. As will be appreciated by those of skill in the art in view of the present disclosure, the etchant 24 may include another etchant (or etchants) and remain within the scope of the present disclosure.

The etchant supply valve 204 is connected to the etchant source 202 and is configured to provide selective fluid communication between the etchant source 202 and the exhaust arrangement 106. In this respect it is completed that the etchant supply valve 204 include a valve member supported for movement within the etchant supply valve 204 between a closed position, wherein the etchant supply valve 204 fluidly separates the etchant source 202 from the exhaust arrangement 106, and an open position, wherein the etchant supply valve 204 fluidly couples the etchant source 202 to the exhaust arrangement 106.

In certain examples, the etchant supply valve 204 may have a manual actuator to move the valve member within the etchant supply valve 204 between the open position and the closed position. In accordance with certain examples, the etchant supply valve 204 may have an electrical or pneumatic actuator to move the valve member within the etchant supply valve 204 between the open position and the closed position. In such examples the etchant supply valve 204 may be operably associated with the controller 108, which allows the controller 108 to selectively provide the etchant to the exhaust arrangement 106 according to the amount of accretion indicated by the accretion sensor 110 through the accretion signal 22.

It is contemplated that the etchant supply valve 204 be fluidly coupled to the exhaust arrangement 106 by the etchant supply conduit 206, the etchant supply conduit 206 flowing the etchant 24 to the exhaust arrangement 106 when the valve member within the etchant supply valve 204 is in the open position. It is contemplated that the etchant supply conduit 206 bypass the chamber arrangement 106, the etchant 24 provided by the etchant source 202 thereby arriving at the exhaust arrangement 106 without traversing the chamber arrangement 106. As will be appreciated by those of skill in the art in view of the present disclosure, flowing the etchant 24 to the exhaust arrangement 106 within traversing the chamber arrangement 104 limits the effect that the etchant 24 could otherwise have on components within the chamber arrangement 106, improving chamber component lifetime by avoiding unnecessary etching within the chamber arrangement 104 when removing accreted material from within the exhaust arrangement 106.

In certain examples, the etchant supply conduit 206 may be connected to an etchant port 208 arranged along the exhaust conduit 178 and located between the isolation valve 180 and the pressure control valve 182. As will be appreciated by those of skill in the art in view of the present disclosure, so positioned, the etchant 24 may be introduced into the exhaust conduit 178 at a location upstream of the pressure control valve 182. This facilitates accretion removal in-situ, i.e., without disassembly of the exhaust arrangement 106, as the etchant may therefore be drawn across the pressure control valve 182 and thereafter the accretion sensor 110 by the exhaust pump 186 prior to communication to the external environment 18 via a scrubber or other abatement device. As will also be appreciated by those of skill in the art in view of the present disclosure, the etchant port 208 may be located at other positions along the exhaust conduit 178, e.g., between the accretion sensor 110 and pressure control valve 182 or between the accretion sensor 110 and the maintenance valve 184, and remain within the scope of the present disclosure.

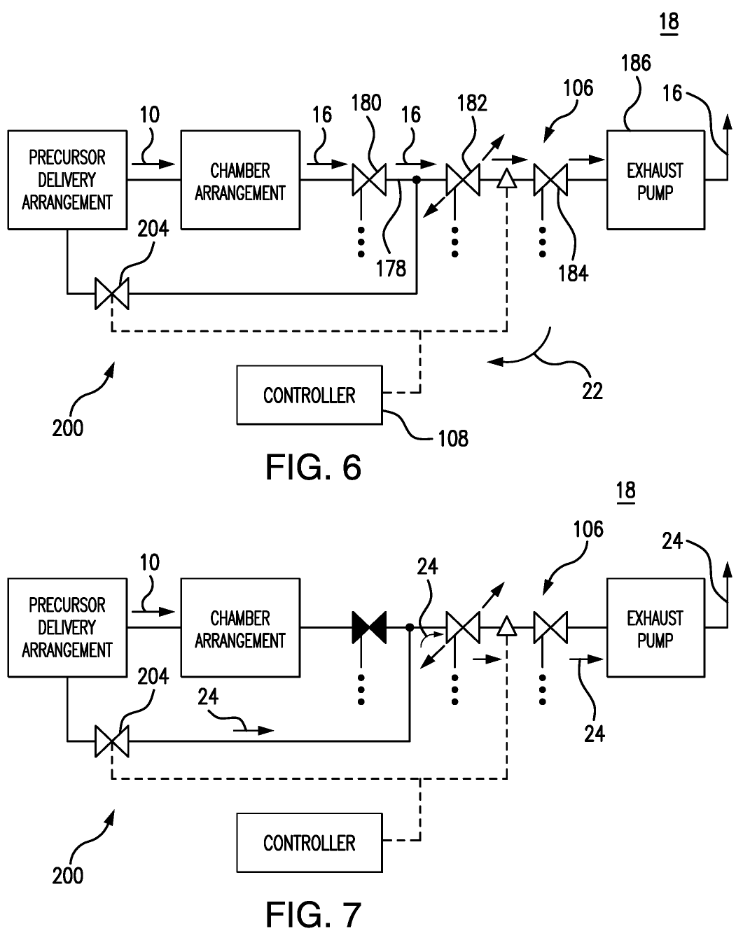

With reference to FIGS. 6 and 7, control of accretion within the exhaust arrangement 106 is shown. As shown in FIG. 6, when the amount of accretion disposed within the exhaust arrangement 106 indicated in the accretion signal 22 is below a predetermined accretion amount value, no action is taken. In this respect the isolation valve 180 and the maintenance valve 184 remain open, the pressure control valve 182 throttles flow through the exhaust conduit 178 to maintain a predetermined material layer deposition pressure within the chamber arrangement 106, and the etchant supply valve 204 remains closed such that no etchant flows from the etchant source 202 to the exhaust arrangement 106. As will be appreciated by those of skill in the art in view of the present disclosure, the chamber arrangement 106 may be employed to deposit material layers onto substrates, e.g., the material layer 12 (shown in FIG. 3) onto the substrate 14 (shown in FIG. 2), without interruption. It is contemplated that the exhaust arrangement 106 communicate the residual precursor and/or reaction products 16 to the external environment 18 while the accretion signal 22 indicates that accumulated accretion associated with the residual precursor and/or reaction products 16 flowing through the exhaust arrangement 106 remains below the predetermined accretion amount value.

As shown in FIG. 7, when the accretion signal 22 provided by the accretion sensor 110 exceeds the predetermined accretion amount value, the controller 108 may execute a countermeasure. For example, the controller 108 may provide a user output to a user, e.g., a user output 32 (shown in FIG. 2) through the user interface 116 (shown in FIG. 2), the user thereafter removing accreted material from within the exhaust conduit 178 by opening the etchant supply valve 204 and flowing the etchant 24 to the exhaust arrangement 106. As will be appreciated by those of skill in the art in view of the present disclosure, providing a user output allows the user to address accretion formation within the exhaust arrangement 106 prior to the accretion reaching a size at which material layer deposition within the chamber arrangement 106. As will also be appreciated by those of skill in the art in view of the present disclosure, provision of a user output also allows the user to limit impact to operation of the semiconductor processing system 200, for example, by completing deposition of the material layer on the substrate then in process within the chamber arrangement 106 prior to providing the etchant 24 to the exhaust arrangement 106.

In certain examples, the countermeasure executed by the controller 108 may include closing the isolation valve 180 prior to providing the etchant 24 to the exhaust arrangement 106. Closing the isolation valve 180 prior to providing the etchant 24 to the exhaust arrangement 106 fluidly separates the chamber arrangement 106 for the exhaust arrangement 106, preventing the etchant 24 from influencing processing conditions within the chamber arrangement 106 that could otherwise occur from back streaming of the etchant from the exhaust conduit 178 into the chamber arrangement 106. As will be appreciated by those of skill in the art in view of the present disclosure, limiting (or preventing) change to processing conditions within the chamber arrangement 106 reduces the downtime to the semiconductor processing system 200 associated with removal of accretion from within the exhaust arrangement 106, improving availability of the semiconductor processing system 200.

In accordance with certain examples, the accretion signal 22 provided by the accretion sensor 110 may be employed for endpoint detection during accretion removal from the exhaust arrangement 106. In this respect it is contemplated that the controller 108 close the etchant supply valve 204 when the accretion signal 22 indicates that the amount of accretion within the exhaust arrangement 106 falls to below the predetermined accretion amount value during provision the etchant 24 to the exhaust conduit 106. Advantageously, employing the accretion sensor 110 for end point detection allows accretion from within the exhaust arrangement 106 to be removed in-situ without requiring disassembly of the exhaust arrangement 106 for visual inspection of interior surfaces. As will be appreciated by those of skill in the art in view of the present disclosure, this limits (or eliminates entirely) potential hazards that could otherwise be associated by exposing maintainers to residual accretions located within the exhaust arrangement 106 subsequent to cleaning, such as hydrochloric acid (which can adsorb from interior surfaces upon exposure to ambient pressure) and arsenic by way of non-limiting example.

With reference to FIG. 8, a semiconductor processing system 300 is shown. The semiconductor processing system 300 is similar to the semiconductor processing system 100 (shown in FIG. 1) and is additionally configured to heat the exhaust arrangement 106, internally, to facilitate removal of accretion from within the exhaust arrangement 106. In this respect the semiconductor processing system 300 includes an etchant source 302 and a reducing agent source 304. The semiconductor processing system 300 also includes an etchant supply valve 306, an etchant supply conduit 308, and a reducing agent tee 310. The semiconductor processing system 300 further includes a reducing agent supply valve 312, reducing agent supply conduit 314, and a reduction-oxidation (redox) product/etchant conduit 316. As will be appreciated by those of skill in the art in view of the present disclosure, the semiconductor processing system 300 may include additional features and/or omit illustrated features in other examples and remain within the scope of the present disclosure.

The etchant source 302 includes the etchant 24 and is connected to the etchant supply valve 306. The etchant supply valve 306 is in turn connected to the etchant supply conduit 308, and therethrough to the exhaust arrangement 106 through the reducing agent tee 310 and the redox product/etchant conduit 316, and is configured to provide the etchant 24 for intermixing with a reducing agent 34 at the reducing agent tee 310. In certain examples, the etchant supply valve 306 may include a manual actuator. In accordance with certain examples, the etchant supply valve 306 may include an electrical actuator, such as a solenoid or through incorporation in a mass flow controller (MFC) device. It is contemplated that the etchant supply valve 306 be operably associated with the controller 108, such as through the wired or wireless link 112, for cooperation with the reducing agent supply valve 312 and/or the isolation valve 180.

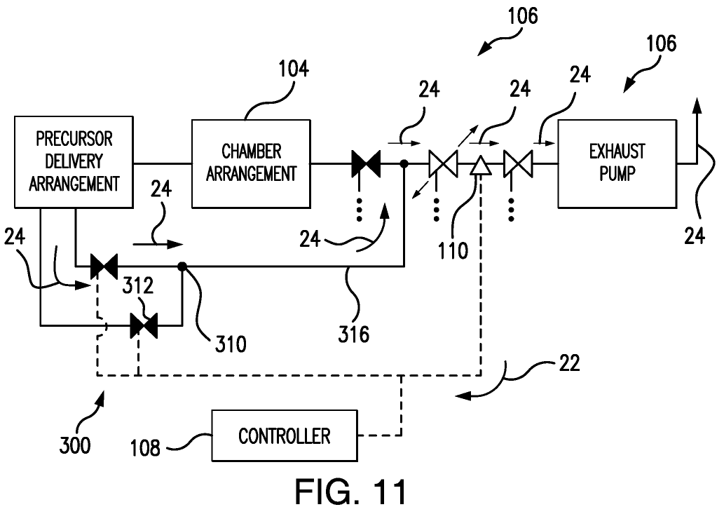

The reducing agent source 304 includes the reducing agent 34 and is connected to the reducing agent supply valve 312. The reducing agent supply valve 312 is in turn connected to the reducing agent supply conduit 314, and therethrough to the exhaust arrangement 106 through the reducing agent tee 310 and the redox product/etchant conduit 316, and is configured to provide the reducing agent 34 to the reducing agent tee 310. It is contemplated that reducing agent 34 intermix with the etchant 24 at reducing agent tee 310, and that the intermixed reducing agent 34 and etchant 24 undergo a reduction-oxidation (redox) reaction within the redox product/etchant conduit 316 to form a reduction product 36. It is further contemplated that the redox reaction be exothermic, and the reduction product thereby heat exhaust arrangement 106 using heat H (shown in FIG. 11) generated by the redox reaction. In certain examples, duration and/or mass flow of the reducing agent 34 is selected such that heating of the exhaust arrangement 106 raises temperature of accretions within the exhaust arrangement 106 whereat the accretions may be rapidly etched by the etchant 24. In accordance with certain examples, the reducing agent supply valve 312 may include a manual actuator or an electrical actuator, such as a solenoid or an MFC device, and that the reducing agent supply valve 312 be operably associated with the controller 108. Examples of suitable reducing agents include hydrogen (H₂) gas, although other reducing agents may be employed and remain within scope of the present disclosure.

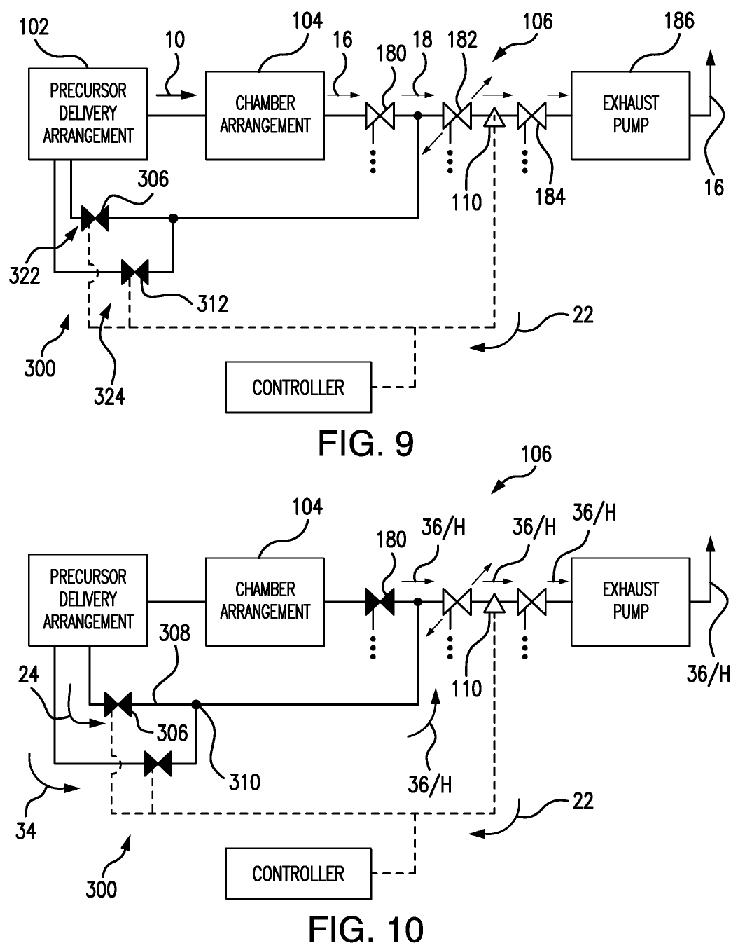

With reference to FIGS. 9-12, the semiconductor processing system 300 is shown when the accretion signal 22 indicates that accretion within the exhaust arrangement is less than a predetermined accretion amount value and when the accretion signal 22 indicates that accretion within the exhaust arrangement 106 is greater than the predetermined accretion amount value. As shown in FIG. 9, when the accretion signal 22 provided by the accretion sensor 110 indicates that accretion within the exhaust arrangement 106 is below the predetermined accretion amount value, material layer deposition may continue without interruption. In this respect it is contemplated that the etchant supply valve 306 remain in a closed position 322, that the reducing agent supply valve 312 remain in a closed position 324, and that the isolation valve 180 and the maintenance valve 184 fluidly couple the exhaust pump 106 to the chamber arrangement 104. As will be appreciated by those of skill in the art in view of the present disclosure, fluidly coupling the exhaust pump 186 to the chamber arrangement 104 allows the pressure control valve 182 to maintain a predetermined material layer deposition pressure within the chamber arrangement 104.

As shown in FIG. 10, when the accretion signal 22 provided by the accretion sensor 110 indicates that accretion within the exhaust arrangement 106 is greater than the predetermined accretion amount value, material layer deposition within the chamber arrangement 104 may be interrupted, such as upon completion of deposition of the material layer on the substrate supported within the chamber arrangement 104 or when substrate scheduling through the semiconductor processing system 300 otherwise permits. Accretion removal is accomplished by closing the isolation valve 180, opening the etchant supply valve 306, and further opening the reducing agent supply valve 312. As will be appreciated by those of skill in the art in view of the present disclosure, closure of the isolation valve 180 fluidly separates the chamber arrangement 104 from the exhaust arrangement 106. As will also be appreciated by those of skill in the art in view of the present disclosure, opening of the etchant supply valve 306 causes the etchant source 302 to flow the etchant 24 to the etchant supply conduit 308, and opening the reducing agent supply valve 312 causes the reducing agent source 304 to flow the reducing agent 34 to the reducing agent supply conduit 314. It is contemplated that the etchant 24 and the reducing agent 34 intermix with one another at the reducing agent tee 310, a reduction-oxidation (redox) reaction occurring therein to produce a redox product 36, which the redox product/etchant conduit 316 provides to the exhaust arrangement 106.

In certain examples the etchant 24 may include (e.g., consist of or consist essentially of) chlorine (Cl₂) gas. In accordance with certain examples, the reducing agent 34 may include (e.g., consist of or consist essentially of) hydrogen (H₂) gas. It also contemplated that, in accordance with certain examples, the etchant 24 may include chlorine (Cl₂) gas and the reducing agent may include hydrogen (H₂) gas, the reduction product 36 in such examples being hydrochloric (HCl) acid. As will be appreciated by those of skill in the art in view of the present disclosure, employed of chlorine (Cl₂) gas and hydrogen (H₂) gas limits the duration of the interval during which hydrochloric acid (HCl) need be generated due to the amount of heat generated by the redox reaction, allowing heating to be accomplished relatively quickly. As will also be appreciated by those of skill in art in view of the present disclosure, other etchants and/or reducing agents may be employed and remain within the scope of the present disclosure.

As shown in FIG. 11, the reducing agent supply valve 312 is thereafter closed. Closure of the reducing agent supply valve 312 ceases flow of the reducing agent 36 to the reducing agent tee 310 such that redox product/etchant conduit 316 thereafter provides only the etchant 24 to the exhaust arrangement 106. Advantageously, the rate at which the etchant 24 removes accreted material from within the exhaust arrangement 106 may be relatively fact due to the heating of the exhaust arrangement 106 by the redox product 36 (shown in FIG. 10). Further, in examples where the redox provide 36 is itself an etchant (e.g., hydrochloric acid), the redox product 36 may roughen exposed surfaces of accreted material within the exhaust arrangement 106, further increasing the rate at which the etchant 24 removes accreted material from within the exhaust arrangement 106. In certain examples, the accretion signal 22 provided by the accretion sensor 110 may provide end point detection, the controller 108 determining when to cease provision of the etchant 24 to the exhaust arrangement 106 by comparing the amount of accreted material indicated by the accretion signal 22 to the predetermined accreted material value.

With reference to FIG. 12, the method 400 of controlling accretion within an exhaust arrangement for a semiconductor processing system, e.g., the exhaust arrangement 106 (shown in FIG. 1) of the semiconductor processing system 100 (shown in FIG. 1), is shown. The method 400 includes receiving an accretion signal, e.g., the accretion signal 22 (shown in FIG. 1) and a predetermined accretion value, as shown with box 410 and box 420. The method 400 also includes comparing the received accretion amount to the received accretion value, as shown with box 430. When the received accretion amount is less than the predetermined accretion value, accretion monitoring continues, as shown with box 440 and arrow 442. When the received accretion value is greater than the predetermined accretion value, an accretion countermeasure is executed, as shown with arrow 444 and box 450.

In certain examples, the countermeasure includes providing a user output to a user interface, as shown with box 452. In accordance with certain examples, the countermeasure may include fluidly separating the exhaust arrangement from a chamber arrangement, e.g., the chamber arrangement 104 (shown in FIG. 1), as shown with box 454. In further examples, the countermeasure may include providing an etchant, e.g., the etchant 24 (shown in FIG. 5), to the chamber arrangement, as shown with box 456. It is also contemplated that, in accordance with certain examples, that the countermeasure may include providing both the etchant and a reducing agent to the chamber arrangement, e.g., the reducing agent 34 (shown in FIG. 8), to heat the chamber arrangement, as shown with box 458. As shown with arrow 460, provision of the etchant to the exhaust arrangement may cease once the accretion signal indicates that the etchant has removed sufficient accretion from within the exhaust arrangement such that the amount of accretion indicated in the accretion signal is less than the predetermined accretion value.

It will be evident that various modifications and changes may be made thereto without departing from the broader spirit and scope of the invention. The specification and drawings are, accordingly, to be regarded in an illustrative rather than restrictive sense. Indeed, it will be appreciated that the systems and methods of the disclosure each have several innovative aspects, no single one of which is solely responsible or required for the desirable attributes disclosed herein. The various features and processes described above may be used independently of one another, or may be combined in various ways. All possible combinations and subcombinations are intended to fall within the scope of this disclosure.

Certain features that are described in this specification in the context of separate embodiments also may be implemented in combination in a single embodiment. Conversely, various features that are described in the context of a single embodiment also may be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open- ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, one or more example methods or processes may be described herein. However, other operations may be incorporated in the example methods and processes. For example, one or more additional operations may be performed before, after, simultaneously, or between any of the specifically provided operations. Additionally, the operations may be rearranged or reordered in other embodiments. Moreover, the separation of various system components in the embodiments described above should not be understood as requiring such separation in all embodiments, and it should be understood that the described program components and systems may generally be integrated together in a single software product or packaged into multiple software products. Additionally, other embodiments are within the scope of the following claims. In some cases, the actions recited in the claims may be performed in a different order and still achieve desirable results.

Accordingly, the claims are not intended to be limited to the embodiments described herein, but are to be accorded the widest scope consistent with this disclosure, the principles, and the novel features disclosed herein.

1. A semiconductor processing system, comprising:
a chamber arrangement;
an exhaust arrangement connected to the chamber arrangement;
an accretion sensor supported within the exhaust arrangement; and
a processor disposed in communication with the accretion sensor and responsive to instructions recorded on a non-transitory machine-readable medium to:
receive an accretion signal from the accretion sensor, the accretion signal indicative of an accretion amount disposed within the exhaust arrangement;
receive a predetermined accretion amount value;
compare the accretion amount to the predetermined accretion amount value; and
execute an accretion countermeasure when the accretion amount is greater than the predetermined accretion amount value.

2. The semiconductor processing system of claim 1, wherein the accretion sensor includes a quartz crystal microbalance (QCM) structure.

3. The semiconductor processing system of claim 2, wherein the exhaust arrangement comprises a foreline assembly connected to the chamber arrangement, and wherein the QCM structure is supported within the foreline assembly.

4. The semiconductor processing system of claim 2, wherein the accretion amount is disposed at least in part on the QCM structure.

5. The semiconductor processing system of claim 1, wherein the exhaust arrangement comprises an exhaust conduit connected to the chamber arrangement, wherein the accretion sensor is supported within the exhaust conduit.

6. The semiconductor processing system of claim 5, further comprising an isolation valve connecting the exhaust conduit to the chamber arrangement, wherein the isolation valve separates the accretion sensor from the chamber arrangement.

7. The semiconductor processing system of claim 5, further comprising a pressure control valve arranged along the exhaust conduit, wherein the pressure control valve is between the accretion sensor and the chamber arrangement.

8. The semiconductor processing system of claim 7, wherein the exhaust conduit has an etchant port, wherein the pressure control valve is between the accretion sensor and the etchant port.

9. The semiconductor processing system of claim 8, further comprising:
an etchant conduit connected to the etchant port; and
an etchant source connected to the etchant conduit and bypassing the chamber arrangement, etchant provided to the exhaust conduit bypassing the chamber arrangement.

10. The semiconductor processing system of claim 9, wherein the etchant source includes chlorine (Cl₂) gas.

11. The semiconductor processing system of claim 5, further comprising a maintenance valve connected to the exhaust conduit, wherein the accretion sensor is supported within the exhaust conduit between the maintenance valve and the chamber arrangement.

12. The semiconductor processing system of claim 1, further comprising:
an exhaust conduit connected to the chamber arrangement, wherein the accretion sensor is supported within the exhaust conduit;
an etchant conduit connected to the exhaust conduit; and
an etchant source connected to the etchant conduit, the etchant conduit bypassing the chamber arrangement.

13. The semiconductor processing system of claim 12, further comprising:
a reducing agent conduit connected to the etchant conduit;
a reducing agent supply valve arranged along the reducing agent conduit;
an etchant supply valve arranged along the etchant conduit; and
wherein the reducing agent conduit is connected to the etchant conduit between the etchant supply valve and the exhaust conduit to introduce a reducing agent into an etchant provided by the etchant source within the etchant conduit.

14. The semiconductor processing system of claim 13, wherein the etchant supply valve and the reducing agent supply valve are operably associated with the processor to heat the exhaust conduit using heat generated by reducing the etchant with the reducing agent within the etchant conduit.

15. The semiconductor processing system of claim 13, wherein the etchant source comprises chlorine (Cl₂) gas, wherein the reducing agent comprises hydrogen (H₂) gas.

16. The semiconductor processing system of claim 1, further comprising a precursor delivery arrangement, the precursor delivery arrangement comprising:
a silicon-containing precursor source connected to the chamber arrangement and therethrough to the exhaust arrangement;
an etchant source connected to the exhaust arrangement by an etchant conduit, the etchant conduit bypassing the chamber arrangement such that etchant provided to the exhaust arrangement does not traverse the chamber arrangement; and
a reducing agent source connected to the etchant conduit such that reducing agent provided to the exhaust arrangement does not traverse the chamber arrangement.

17. The semiconductor processing system of claim 1, wherein the countermeasure executed by the processor comprises:
fluidly separating the exhaust arrangement from the chamber arrangement;
fluidly coupling the exhaust arrangement to an etchant source;
fluidly coupling the exhaust arrangement to a reducing agent source; and
heating the exhaust arrangement using a reducing agent provided by the reducing agent source and an etchant provided by the etchant source.

18. The semiconductor processing system of claim 1, wherein the chamber arrangement comprises susceptor supported from rotation within a chamber body, the chamber body configured to flow a material layer precursor across a substrate seated on the susceptor.

19. An accretion control method, comprising:
at a semiconductor processing system including a chamber arrangement, an exhaust arrangement connected to the chamber arrangement, an accretion sensor supported within the exhaust arrangement, and a processor disposed in communication with the accretion sensor and a memory including a non-transitory machine-readable medium,
receiving, at the processor, an accretion signal from the accretion sensor indicative of an accretion amount disposed within the exhaust arrangement;
receiving, at the processor, a predetermined accretion amount value;
comparing, with the processor, the accretion amount to the predetermined accretion amount value;
executing, with the processor, an accretion countermeasure when the accretion amount is greater than the predetermined accretion amount value; and
wherein the countermeasure includes at least one of (a) providing a user output to a user interface operably associated with the processor, (b) fluidly separating the exhaust arrangement from the chamber arrangement, (c) providing an etchant to the exhaust arrangement, and (d) providing a reducing agent to the exhaust arrangement to heat the exhaust arrangement.

20. A foreline assembly for a semiconductor processing system, comprising:
an exhaust conduit;
an isolation valve and a maintenance valve arranged along the exhaust conduit configured to fluidly couple the semiconductor processing system to an exhaust pump;
a pressure control valve between the isolation valve and the maintenance valve configured to control pressure within a chamber arrangement of the semiconductor processing system;
an accretion sensor is arranged within the exhaust conduit between the pressure control valve and the maintenance valve to provide an accretion signal indicating an accretion amount within the exhaust conduit; and
wherein the exhaust conduit has an etchant port is defined along the exhaust conduit between the isolation valve and the pressure control valve to remove the accretion amount from within the exhaust conduit using an etchant using the accretion signal.
